(19) United States
(12) Patent Application Publication
(10) Pub. No.: US 2011/0127544 A1
(43) Pub. Date: Jun. 2, 2011

(54) GROUP III NITRIDE TEMPLATES AND RELATED HETEROSTRUCTURES, DEVICES, AND METHODS FOR MAKING THEM

(75) Inventors: Tanya Paskova, Raleigh, NC (US); Edward A. Preble, Raleigh, NC (US); Terry L. Clites, Raleigh, NC (US); Andrew D. Hanser, Raleigh, NC (US); Keith R. Evans, Raleigh, NC (US)

(73) Assignee: KYMA TECHNOLOGIES, Raleigh, NC (US)

(21) Appl. No.: 12/991,180

(22) PCT Filed: May 6, 2009
(86) PCT No.: PCT/US09/42949

§ 371 Date: Feb. 16, 2011

Related U.S. Application Data
(60) Provisional application No. 61/126,680, filed on May 6, 2008.

(51) Int. Cl. H01L 29/161; H01L 29/12; H01L 29/20; H01L 21/20; B82Y 99/00; B82Y 40/00

(52) U.S. Cl. 257/77; 257/201; 257/76; 438/478; 977/700; 977/840; 257/E21.09; 257/E29.089; 257/E29.084; 257/E29.068

(57) ABSTRACT

A templated substate includes a base layer, and a template layer disposed on the base layer and having a composition including a single-crystal Group Ill nitride. The template layer includes a continuous sublayer on the base layer and a nanocolumnar sublayer on the first sublayer, wherein the nanocolumnar sublayer includes a plurality of nano-scale columns.

### CROSS-REFERENCE TO RELATED APPLICATIONS

This application claims the benefit of U.S. Provisional Patent Application Ser. No. 61/126,680, filed May 6, 2008, titled “Group III Nitride Sputtered Template for Fabricating Group III Nitride Heterostructures and Devices, and Group III Nitride Structures Including the Template,” the content of which is incorporated by reference herein in its entirety.

### BACKGROUND

1. Technical Field

The present invention generally relates to Group III nitride-inclusive templates useful in the fabrication of various heterostructures and microelectronic devices, as well as heterostructures and microelectronic devices based on such templates. In particular, the invention relates to templated substrates associated heterostructures and microelectronic devices that include a nanocolumnar template layer.

2. Description of the Related Art

The choice of an optimal substrate is considered to be a key factor in the epitaxial growth of high-quality semiconductor materials. The longstanding demand for native nitride substrates for homoepitaxial growth of Group III nitride devices has still not been satisfied. Instead, foreign substrates have been utilized for most of the nitride applications despite the well-known disadvantageous consequences of the heteroepitaxy (e.g., mismatches in lattice constants and thermal expansion coefficients). Sapphire is the most commonly utilized based substrate in the heteroepitaxial growth of Group III nitride layers. In addition to sapphire substrates, several other substrates such as SiC, GaAs, Si, and certain oxide substrates such as LiAlO₂, MgAl₂O₄ and MgO have been intensively studied.

Because the lattice mismatch and the thermal expansion coefficient mismatch with available substrates are both very large, growth optimizations have been examined by many groups to determine whether the properties of the nitride layers and device structures could be improved, particularly with respect to structural defects and residual strain. Several growth approaches have been suggested and have proven to lead to significant improvements in crystal quality and device performance. These growth approaches may generally be classified into three main groups: (i) multi-step buffers, (ii) complex-structure interface templates (complex-patterned structures) and (iii) template layers of different compound materials.

Multi-step buffers, or low-temperature (LT) buffers, in principle consist of one low-temperature (LT) nucleation layer, which recrystallizes during heating up to higher temperature (HT), and a single crystalline layer deposited at the higher temperature. That is, a nucleation layer is grown at low temperature on the underlying foreign substrate, and then the single-crystal layer is deposited at a higher growth temperature. A device structure may then be deposited on this two-step buffer structure. There are a number of different types of these LT buffers. They vary in type of material (GaN, AlN, AlGaN), in composition of the ternary alloy, in their thicknesses, and in the particular growth conditions utilized. In addition, the number of buffer pairs (LT nucleation—HT single crystalline) layers may vary from one to several. The LT layers in the second pair, third pair, etc. are often termed LT interlayers. These approaches have been proven to improve the overall quality of the nitride layers. Layers with specular surfaces, free from cracks and pits, with no columnar structure have been achieved, the dislocation density and the background carrier concentration significantly reduced, the carrier mobility strongly increased, and luminescence properties markedly improved. The simple explanation of the influence of the low temperature buffers on the properties of the main layers is that the buffers induce a defect-rich zone in the subsequent high temperature nitride layer. In this faulted zone of some 50 nm, structural defects rapidly recombine by lateral growth and a high quality epitaxial layer forms on top. The different types of LT buffers have been optimized for different device applications in commercial production volume.

Complex-structure interface templates have been suggested with the main goal of further reducing the dislocation density and improving the device performance. Fabrication of these templates requires several technological process steps, including forming patterns with different shapes (stripe, hexagonal, oval openings), different periods, and different thicknesses. These patterns are formed of a single-crystalline thin layer, which itself is grown by employing a LT buffer technology. Then the single-crystalline layer is etched selectively through a mask of a different material (SiO₂, W, SiN) deposited on top of the single-crystalline layer. There are a number of different approaches known to persons skilled in the art, including epitaxial lateral overgrowth (ELOG), selective area overgrowth (SAOG), pendeoepitaxy, etc. These growth techniques have been proven to be very effective in reducing the dislocation density, especially in some areas where the lateral growth modes dominate. At the same time, however, more defects have been formed in other areas where the coalescence takes place, such as dislocations of different types and voids. Moreover, the low defect-density areas have been found to experience much higher conductivity due to enhanced impurity incorporation. Nevertheless, the low-defect density area permits fabrication of devices with significantly improved performance and are presently widely used in semiconductor manufacture of certain types of nitride devices. These techniques remain, however, quite complicated, time-consuming and expensive.

Template single layers of alternative materials have been suggested with the same main goal of improving the crystal quality and device performance when the LT buffer approach is not considered desirable due to inability to perform reasonable growth at low temperature. For example, in the hydride vapor phase epitaxy (HVPE) of GaN, the LT buffer approach has not been successful, and consequently separately deposited template layers by different techniques have been required. Several template layers have been studied such as ZnO, CrN, TiN, SiN, GaN, AlN. These types of template layers have been developed with the assumption that they will act in a different way to achieve a particular purpose. These types of template layers may be classified into three groups based on their main function. The first group includes layers such as ZnO and CrN that provide good transition on the foreign substrates, resulting in good crystal quality of the GaN layers, and can also be chemically dissolved leading to substrate delamination and producing free-standing nitride layers. The second group includes layers such as TiN and SiN that recrystallize during heating up and initial stages of the next layer growth by forming islands and void defects. Thus, they form a weak interface region where strain will be accumulated and cracks will occur preferably leading also to self separation of the substrate. The third group includes single crystalline layer templates such as 2-5 μm thick MOCVD GaN layers or 1-2 μm thick reactive sputtered AlN layers, which ensure good crystal quality of the main layer of interest and remain in the final structure.

While the heteroepitaxial approaches summarized above have demonstrated improvements in crystal quality and device performance, they require a complex combination of process steps and are expensive. Therefore, the need remains for providing an inexpensive template as a good match between different foreign substrates and nitride layers to produce good crystal structure and improved device performance.

### SUMMARY

To address the foregoing problems, in whole or in part, and/or other problems that may have been observed by persons skilled in the art, the present disclosure provides methods, processes, systems, apparatus, instruments, and/or devices, as described by way of example in implementations set forth below.

According to one implementation, a templated substrate includes a base layer, and a template layer disposed on the base layer and having a composition including a single-crystal Group III nitride. The template layer includes a continuous sublayer on the base layer and a nanocolumnar sublayer on the first sublayer, wherein the nanocolumnar sublayer includes a plurality of nano-scale columns.

According to another implementation, a heterostructure includes a base layer, a template layer disposed on the base layer and having a composition including a single-crystal Group III nitride, and a Group III nitride-inclusive growth layer. The template layer includes a continuous sublayer on the base layer and a nanocolumnar sublayer on the first sublayer, wherein the nanocolumnar sublayer includes a plurality of nano-scale columns. The Group III nitride-inclusive heterostructure is disposed on the nanocolumnar sublayer.

According to another implementation, a microelectronic device includes a base layer, a template layer disposed on the base layer and having a composition including a single-crystal Group III nitride, and a Group III nitride-inclusive device structure. The template layer includes a continuous sublayer on the base layer and a nanocolumnar sublayer on the first sublayer, wherein the nanocolumnar sublayer includes a plurality of nano-scale columns. The Group III nitride-inclusive device structure is disposed on the nanocolumnar sublayer.

According to another implementation, a method is provided for fabricating a templated substrate. A single-crystal Group III nitride-inclusive template layer is grown on a base layer by vacuum deposition, by forming a continuous sublayer on the base layer, and forming a nanocolumnar sublayer on the continuous sublayer wherein the nanocolumnar sublayer comprises a plurality of nano-scale columns.

According to another implementation, a method is provided for fabricating a heterostructure. A single-crystal Group III nitride-inclusive template layer is grown on a base layer by vacuum deposition, by forming a continuous sublayer on the base layer, and forming a nanocolumnar sublayer on the continuous sublayer wherein the nanocolumnar sublayer comprises a plurality of nano-scale columns. A Group III nitride-inclusive heterostructure is grown on the nanocolumnar sublayer.

According to another implementation, a method is provided for fabricating a microelectronic device. A single-crystal Group III nitride-inclusive template layer is grown on a base layer by vacuum deposition, by forming a continuous sublayer on the base layer, and forming a nanocolumnar sublayer on the continuous sublayer wherein the nanocolumnar sublayer comprises a plurality of nano-scale columns. A Group III nitride-inclusive device structure is grown on the nanocolumnar sublayer.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIG. 1 is a cross-sectional view of a templated (or template-inclusive) substrate according to one implementation.

FIG. 2A is an atomic force microscopy (AFM) image (two-dimensional in-plane view) of a representative nanocolumnar template layer illustrating its columnar surface structure.

FIG. 2B is an atomic force microscopy (AFM) image (three-dimensional) of the representative nanocolumnar template layer illustrating its columnar surface structure.

FIG. 2C is a roughness line-scan surface profile across the surface of the representative nanocolumnar template layer illustrating its columnar surface structure.

FIG. 3A is an x-ray diffraction (XRD) phi-scan of a representative nanocolumnar template layer illustrating its crystallographic structure.

FIG. 3B is a XRD 2θ/ω scan of the representative nanocolumnar template layer illustrating its crystallographic structure.

FIG. 4A is a XRD ω scan of a representative nanocolumnar template layer illustrating distinct sublayers of the template layer.

FIG. 4B is a reciprocal space map (RSM) of the representative nanocolumnar template layer illustrating distinct sublayers of the template layer.

FIGS. 5A, 5B and 5C are AFM images of representative nanocolumnar template layers deposited at different temperatures.

FIGS. 6A, 6B and 6C are AFM images of representative nanocolumnar template layers deposited to different thicknesses.

FIG. 7 is a collection of XRD 2θ/ω scans around the symmetric 002 reflection of representative nanocolumnar template layers of different thicknesses.

FIG. 8 is a set of XRD RSMs of representative template layers grown on sapphire substrates with different surface miscuts.

FIGS. 9A and 9B are AFM images of representative template layers grown on SiC and Si base layer, respectively.

FIGS. 10A and 10B are RSMs of representative template layers grown on SiC and Si base layer, respectively.

FIG. 11A is a schematic cross-sectional view of an example of a conventional LED device.

FIG. 11B is a schematic cross-sectional view of an example of a LED device fabricated according to the present teachings.

FIG. 12A is a perspective view of a templated substrate as taught herein, on which a mask has been deposited and patterned.

FIG. 12B is a perspective view of the templated substrate illustrated in FIG. 12B, after etching and mask removal.

FIG. 13 is a schematic time schedule comparing the shorter time required to fabricate a standard MOCVD LED device utilizing a templated substrate as taught herein (solid line) with the longer time required to fabricate the same LED device utilizing a conventional LT buffer nucleation process (dashed line).

### DETAILED DESCRIPTION

For purposes of the present disclosure, it will be understood that when a layer (or film, region, substrate, component, device, or the like) is referred to as being “on” or “over” another layer, that layer may be directly or actually on (or over) the other layer or, alternatively, intervening layers (e.g., buffer layers, transition layers, interlayers, sacrificial layers, etch-stop layers, masks, electrodes, interconnects, contacts, or the like) may also be present. A layer that is “directly on” another layer means that no intervening layer is present, unless otherwise indicated. It will also be understood that when a layer is referred to as being “on” (or “over”) another layer, that layer may cover the entire surface of the other layer or only a portion of the other layer. It will be further understood that terms such as “formed on” or “disposed on” are not intended to introduce any limitations relating to particular methods of material transport, deposition, fabrication, surface treatment, or physical, chemical, or ionic bonding or interaction.

Unless otherwise indicated, the term “Group III nitride” is intended to describe binary, ternary, and quaternary Group III nitride-based compounds such as, for example, gallium nitride, indium nitride, aluminum nitride, aluminum gallium nitride, indium gallium nitride, indium aluminum nitride, and aluminum indium gallium nitride, and alloys, mixtures, or combinations of the foregoing, with or without added dopants, impurities or trace components, as well as all possible crystalline structures and morphologies, and any derivatives or modified compositions of the foregoing. Unless otherwise indicated, no limitation is placed on the stoichiometries of these compounds. Thus, the term “Group III nitride” encompasses Group III nitrides and nitride alloys; that is, AlₓGa_{y}In_{z}N (x+y+z=1, 0≦x≦1, 0≦y≦1, 0≦z≦1), or (Al, Ga, In)N.

As used herein, the term “nanocolumn” or “nano-scale column” generally refers to a columnar structure having at least one characteristic dimension that is less than 1 μm. A characteristic dimension in this context means the height (e.g., lengthwise dimension) or lateral dimension (e.g., diameter) of the column. In one non-limiting example, a “nanocolumn” or “nano-scale column” is a columnar structure that has a height of about 20 nm or less, or a lateral dimension of about 150 nm or less.

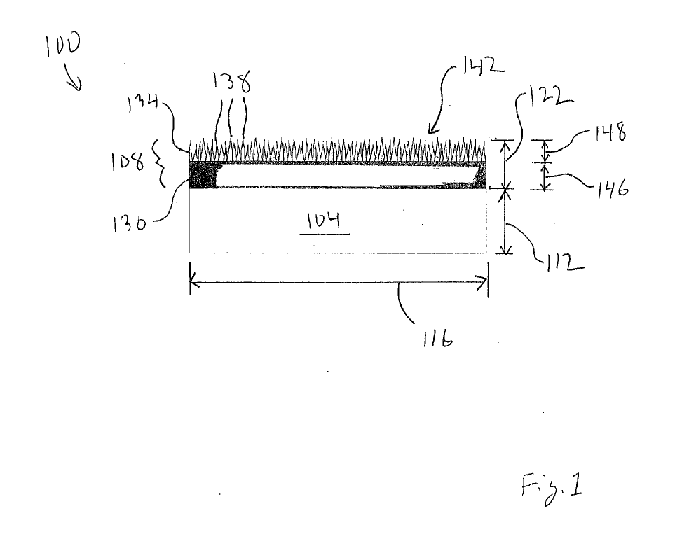

FIG. 1 is a cross-sectional view of a templated (or template-inclusive) substrate 100 according to one implementation. The templated substrate 100 may also be referred to as a template. The templated substrate 100 includes a base layer 104 (or base substrate) on which a nanocolumnar template layer 108 is grown. In typical implementations, the base layer 104 and the template layer 108 comprise different materials and thus the base layer 104 may be referred to as a foreign layer or foreign substrate. In typical implementations, the base layer 104 may be sapphire (Al₂O₃), silicon carbide (SiC) such as for example 6H-SiC or 4H-SiC, or silicon (Si). The base layer 104 may however include other compositions such as, but not limited to, spinel (MgAl₂O₄) or lithium gallate (LiGaO₂). Other possible compositions for the base layer 104 include diamond, carbon (C), diamond-like carbon (DLC), lithium aluminate (LiAlO₂), ScAlMgO₄, zinc oxide (ZnO), magnesium oxide (MgO), gallium arsenide (GaAs), glass, tungsten (W), molybdenum (Mo), hafnium (Hf), zirconium (Zr), zirconium nitride (ZrN), silicon-on-insulator (SOI), carbonized SOI, and other various nitrides and oxides. Moreover, the base layer 104 may be a conductive, insulating, semi-insulating, twist-bonded, compliant, or patterned substrate. The template layer 108 is composed of, or has a composition that includes, a Group III nitride, i.e., (Al, Ga, In)N as defined above. In some preferred implementations, the template layer 108 is AlN or GaN.

The base layer 104 may have any crystallographic or off-cut (miscut) orientation of possible interest. If desired, the crystallographic orientation of the surface of the base layer 104 on which the template layer 108 is grown may be selected so as to ensure polar, nonpolar, or semipolar nitride heteroepitaxy (e.g., c-plane, m-plane, a-plane, r-plane, etc.). See U.S. Patent Application Pub. No. 2009/0081857, assigned to the assignee of the present disclosure and incorporated by reference herein in its entirety. The base layer 104 may have any size and shape suitable for growing the template layer 108 and consequently providing a templated substrate 100 of device quality. As non-limiting examples, the base layer 104 may be cylindrical or disk-shaped or may be polygonal or prismatic. The size of the base layer 104 is generally characterized by a thickness 112 in the growth direction and a lateral dimension 116 generally orthogonal to the thickness 112. From the perspective of FIG. 1, the direction of thickness 112 is vertical, but it will be understood that the orientation of the templated substrate 100 presented in FIG. 1 is arbitrary and merely an example. The lateral dimension 116 is any dimension characteristic of the shape of the base layer 104. As examples, the lateral dimension 116 may be a diameter in the case of a cylindrical or disk-shaped base layer 104, or may be a width or length (i.e., the distance between two opposing sides or corners/vertices/apices) in the case of a polygonal or prismatic base layer 104. In some preferred implementations, the lateral dimension 116 is two inches or greater to facilitate fabrication of a templated substrate 100 of suitable size for use in the fabrication of various heterostructures and devices.

The template layer 108 is grown on the base layer 104 by any technique that results in the structure described herein. In typical implementations, the template layer 108 is grown by a vacuum deposition technique. In some preferred implementations, the template layer 108 is grown by physical vapor deposition (PVD), although other techniques such as chemical vapor deposition (CVD) may be suitable. In some preferred implementations, particularly where the template layer 108 is AlN, the template layer 108 is grown by sputtering and particularly, plasma-enhanced (or plasma-assisted) sputtering. The template layer 108 has a thickness 122 in the growth direction and a lateral dimension. The lateral dimension of the template layer 108 may be coextensive with that of the base layer 104, and thus in some preferred implementations the lateral dimension of the template layer 108 is two inches or greater. In typical examples, the thickness 122 of the template layer 108 ranges from 100-10,000 Å (10-1000 nm). In other examples, the thickness 122 of the template layer 108 may be greater than 100 Å or less than 10,000 Å.

According to the present teachings, the template layer 108 is structured so as to provide a good transition between the foreign base layer 104 and subsequently grown nitride layers (not shown). The template layer 108 is structured so as to accumulate defects and strain, thereby resulting in good crystal quality of any device structure subsequently grown on the template layer 108. As illustrated in FIG. 1, the template layer 108 includes two self-formed sublayers, a first (or continuous) sublayer 130 characterized by a continuous morphology and a second (or nanocolumnar) sublayer 134 characterized by a nanocolumnar morphology. Both the continuous sublayer 130 and the nanocolumnar sublayer 134 may have a single-crystal morphology. The transition from the continuous sublayer 130 to the nanocolumnar sublayer 134 may be characterized by the beginning of distinct columns 138 that are spaced from each other in the lateral dimension. Stated in another way, the transition from the nanocolumnar sublayer 134 to the continuous sublayer 130 occurs where the bases of the columns 138 merge. Accordingly, the nanocolumnar morphology may be generally characterized by the presence of distinct columns 138, and the continuous morphology may be generally characterized by the absence of columns 138.

The nanocolumnar sublayer 134 exhibits a plurality of nano-scale columns 138 that extend from the continuous sublayer 130 to an uppermost surface 142 of the template layer 108 (i.e., upper surface 142 of the nanocolumnar sublayer 134). In typical implementations, the columns 138 are generally conical. That is, each column 138 tapers from a column base at the continuous sublayer 130 to a relatively sharp column tip at the upper surface 142. In the present context, the term “sharp tip” generally means that the column 138 does not terminate at a flat surface but rather the shape of the column tip is that of a point or a dome with an apex. The lateral dimension of the column tip is visibly less than that of the column base when viewed with the assistance of magnification (e.g., AFM). The uppermost surface 142 of the template layer 108 may be characterized as comprising an ensemble of closely-spaced (nanometer-scale) column tips. When growing subsequent layers on the uppermost surface 142, the nanocolumnar sublayer 134 may contribute to strain relief, stress relief, promotion of epitaxial growth, and lower defect density.

For any given sample templated substrate 100, the dimensions (e.g., height, lateral dimension) of the columns 138 may be uniform or substantially uniform from one column 138 to another, or alternatively may vary from one column 138 to another. In some non-limiting examples, the average lateral dimension of the columns 138 at their respective bases ranges from 10 to 150 nm and the average height of the columns 138 ranges from 1 to 20 nm. In some examples, the lateral dimension of the columns 138 may be referred to as a diameter. In the present context, the term “diameter” assumes that the columns 138 have generally circular cross-sections. It will be understood, however, that the columns 138 may not exhibit perfect circular cross-sections such that “diameter” generally encompasses the characteristic dimension of a column 138 in the direction transverse to the above-mentioned growth direction or thickness direction, i.e., the diameter or lateral dimension occurs along the horizontal direction from the perspective of FIG. 1. Also in the present context, the height of the columns 138 generally corresponds to the growth direction or thickness dimension, i.e., the vertical direction from the perspective of FIG. 1.

The continuous sublayer 130 has a first thickness 146 and the nanocolumnar sublayer 134 has a second thickness 148, again taken in the vertical direction from the perspective of FIG. 1. In typical implementations, the continuous sublayer 130 is thicker than the nanocolumnar sublayer 134. The thickness 148 of the nanocolumnar sublayer 134 corresponds to the height of the columns 138. Thus, in some non-limiting examples, the thickness 148 of the nanocolumnar sublayer 134 ranges from 1 to 20 nm and the total thickness 122 of the template layer 108 (continuous sublayer 130 and nanocolumnar sublayer 134) ranges from 10-1000 nm

In certain examples of the templated substrate 100, the surface roughness of the template layer 108 may be in the range of 0.2-10 nm (RMS), and the strain value e_{zz} of the nanocolumnar sublayer 134 may be in the range of 0.2×10⁻² to 0.8×10⁻². The strain value e_{zz} corresponds to the strain in the direction of growth (z direction) perpendicular to the layer surface, and is calculated from XRD measurements of the peak related to the columns 138. The surface roughness and strain status may be controlled as demonstrated below. The template layer 108 may have a crystal quality characterized by a rocking curve FWHM ranging from 100-500 arcsecs for the nanocolumnar sublayer 134 and ranging from 500-2500 arcsecs for the continuous sublayer 130, as determined by using standard Philips triple axis diffractometer.

The templated substrate 100 described herein and illustrated in FIG. 1 may be utilized as a substrate or template for the direct growth of various low defect-density Group III nitride epitaxial layers, heterostructures and devices. The single-step-grown template layer 108 provides a good match between the base layer 104 of foreign composition and subsequently grown nitride structures. Thus, the use of the templated substrate 100 ensures that such heterostructures or devices have good crystalline quality and excellent performance. The specific characteristics of the template layer 108, particularly of the nanocolumnar sublayer 134 (e.g., column size/surface morphology, strain, etc.), may be tailored to be optimal for subsequent nitride device epitaxy of any desired design or structure. Moreover, the template layer 108 is relatively thin and may be quickly grown in an inexpensive way at intermediate growth conditions (i.e., neither low-temperature nor high-temperature conditions) with the use of an inexpensive growth chamber. By reducing process time and avoiding the need for expensive reagents associated with LT buffers, the templated substrate 100 may be utilized as a desirable replacement for the more time-consuming and expensive multi-step LT buffer technology. The templated substrate 100 may also be incorporated in a device structure comprising complex pattern nucleation for various device applications.

While the template layer 108 includes two distinct sublayers 130 and 134 as described above, the template layer 108 is formed in a single-step process. That is, the two sublayers 130 and 134 are formed utilizing the same growth conditions (e.g., growth rate, growth temperature, gas pressures, gas flow rates, plasma operating parameters, etc.), i.e., the transition from the continuous sublayer 130 to the nanocolumnar sublayer 134 does not require a change in growth conditions. In this sense, the two sublayers 130 and 134 may be characterized as being “self-forming.”

One non-limiting example of fabricating the templated substrate 100 is as follows. A base layer 104 and a Group III metal target are loaded in a sputter deposition chamber. The base layer 104 is typically cleaned before loading by any suitable means and then mounted on a suitable substrate holder. In the chamber, the substrate holder may be placed in contact with a suitable heating device to control substrate temperature. The chamber is then pumped down to an appropriate vacuum pressure. An energetic plasma is generated in the chamber using a background gas such as, for example, argon (Ar). The operating conditions of the plasma may be set to suitable values (e.g., power, frequency, etc.). A separate nitrogen-containing gas is flowed into the chamber. The nitrogen-containing gas may be, for example, diatomic nitrogen or a nitrogen-inclusive compound such as ammonia (NH₃). When both a nitrogen-containing gas and an additional gas (such as a plasma-enabling gas (e.g., Ar) or other type of gas), the operating conditions may be characterized as a mixed-gas environment. Alternatively, the same gas utilized to provide the nitrogen species could also be utilized to generate the plasma, in which case a separate background gas need not be utilized. Gas flows may be controlled by suitable flow controllers. The Group III metal target is then sputtered to produce a Group III metal source vapor. The Group III metal source vapor combines with the nitrogen-containing gas, and reactant vapor species including components of the Group III metal and the nitrogen are deposited on the surface of the base layer 104. Process conditions (e.g., growth rate, growth temperature, gas pressures, gas flow rates, plasma operating parameters, etc.) are controlled as needed to promote the growth of the nanocolumnar template layer 108, and are dependent on the composition of the template layer 108 and specific properties desired (e.g., strain, surface roughness, etc.). In certain specific, yet non-limiting, examples entailing the deposition of an AlN template layer 108, the growth rate is relatively slow, i.e., less than 1 μm/hr. In another specific example, the growth temperature is greater than 500° C. In another specific example, the AlN template layer 108 is grown in a mixed-gas environment at a growth rate of less than 1 μm/hr and at a temperature of greater than 500° C. As noted elsewhere in the present disclosure, the continuous sublayer 130 and the nanocolumnar sublayer 134 may be formed without changing the process conditions. It will also be noted that the templated substrate 100 is fabricated in a completely in-situ process requiring only a few steps, and without needing to break vacuum or perform extraneous steps as in the case of conventional template-fabrication processes.

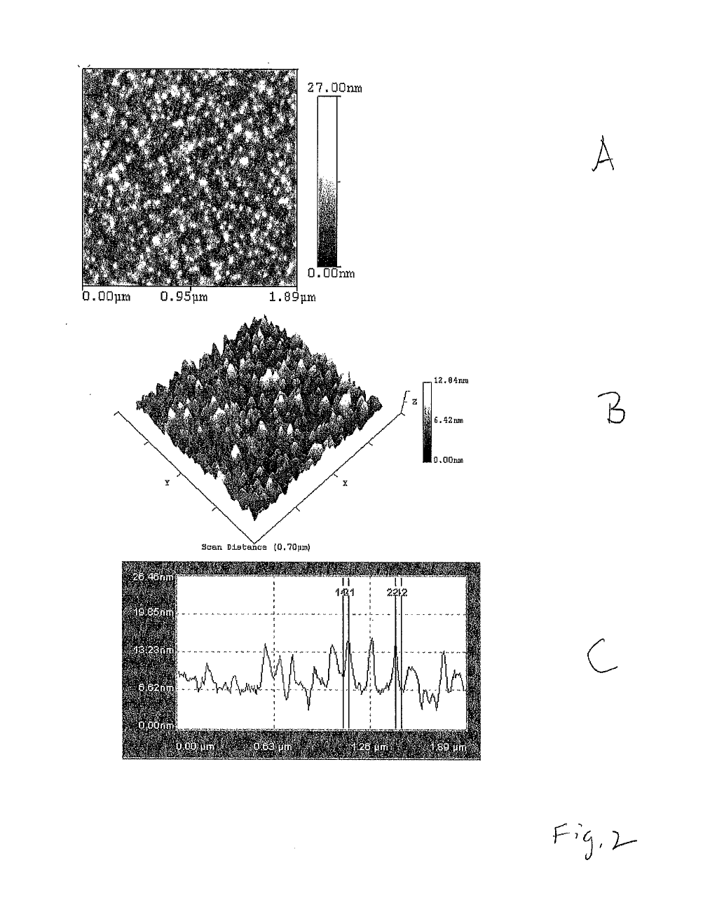

FIGS. 2A to 10B provide analyses of specific samples of the templated substrate 100 fabricated according to the present teachings. In fabricating these samples, an AlN template layer 108 was grown on a base layer 104 by plasma-assisted sputtering. The base layer 104 was sapphire, SiC or Si.

FIG. 2A is an atomic force microscopy (AFM) image (two-dimensional in-plane view) of a representative nanocolumnar template layer illustrating its columnar surface structure. FIG. 2B is an atomic force microscopy (AFM) image (three-dimensional view) of the same nanocolumnar template layer. FIG. 2C is a roughness line-scan surface profile across the surface of the same nanocolumnar template layer. The columns are shown to have an approximately conical shape terminating at a sharp tip. The average lateral dimension of the column bases varies from 10-150 nm. The average height of the columns varies from 1-20 nm. It thus can be seen that the template layer in this example is characterized by varying columnar sizes, which is dependent on growth conditions. The columnar sizes in turn dictate the surface roughness of a given sample. The root-mean-square (RMS) roughness of the upper surface presented by the columns varies from 0.2-10 nm, as calculated from AFM images of various sample templated substrates grown.

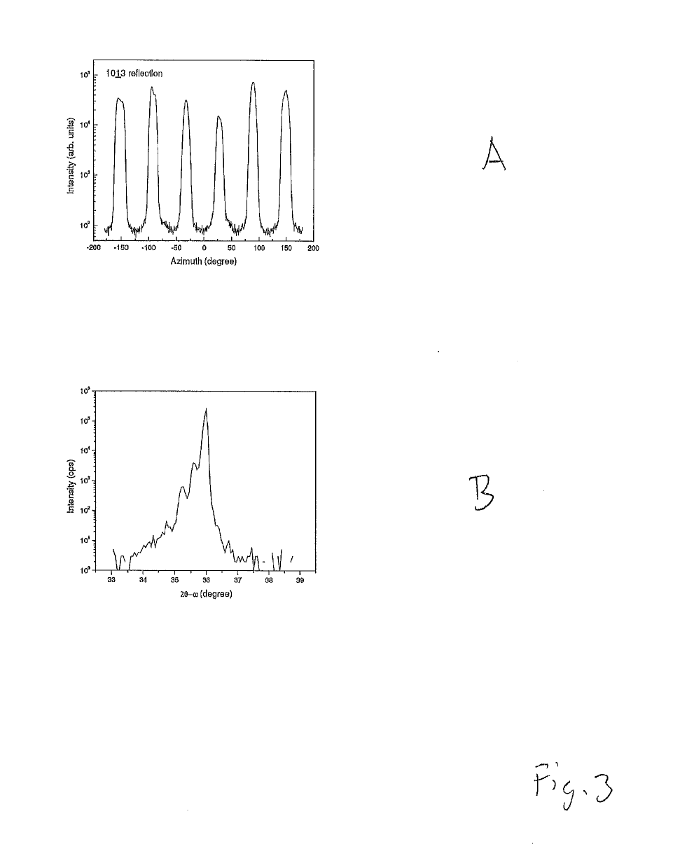

FIG. 3A is an x-ray diffraction (XRD) phi-scan of the same nanocolumnar template layer shown in FIGS. 2A-2C, illustrating its crystallographic structure. Specifically, FIG. 3A illustrates an XRD phi-scan around the asymmetric 10-13 reflection showing six peaks over the azimuth range of 360 degrees, thus implying a 6-fold symmetry that is typical for wurtzite crystals. FIG. 3B is an XRD 2θ/ω scan of the same nanocolumnar template layer also illustrating its crystallographic structure. Specifically, FIG. 3B illustrates a XRD 2θ/ω scan around the symmetric 002 reflection, being the only peak in the wide 2θ range, thus implying a single-crystalline structure of the sputtered layer. FIG. 3B also illustrates a narrow full width at half maximum (FWHM), implying a large coherent length in the growth direction and high crystal quality. FIG. 3B also illustrates several peaks on the lower-angle side analyzed as interference fringes, which is typical for relatively thin layers of high-crystalline quality with parallel interfaces. It thus can be seen that the template layer in this example is characterized by high-quality single-crystalline morphology.

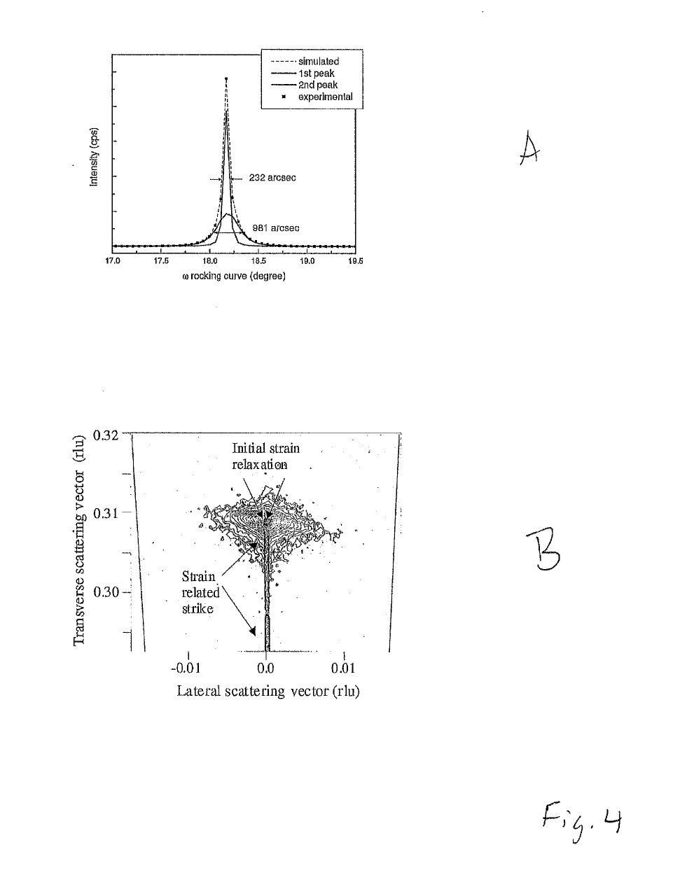

FIG. 4A is an XRD ω scan of the same nanocolumnar template layer shown in FIGS. 2A-2C, evidencing distinct sublayers of the template layer. Specifically, FIG. 4A illustrates an XRD ω scan around the symmetric 002 reflection, showing that the peak is composed of two peaks, thus indicating the presence of a sublayer of high quality and a sublayer containing dislocations and grain tilt. FIG. 4A demonstrates that the single-step-grown template layer has a complex substructure of two self-formed sublayers. FIG. 4B is a reciprocal space map (RSM) of the representative nanocolumnar template layer illustrating distinct sublayers of the template layer. Specifically, FIG. 4B is a RSM around the symmetric 002 reflection. FIG. 4B shows an elongated low-intensity strike at lower transverse scattering vectors, which is indicative of a strained sublayer. FIG. 4B also shows an intensive narrow main peak with slightly elongated wings, which is indicative of a sublayer of high quality with initial partial relaxation. It thus can be seen that the template layer in this example is characterized by exhibiting a complex strain status in which the strain in the nanocolumnar sublayer is different from the strain in the continuous sublayer.

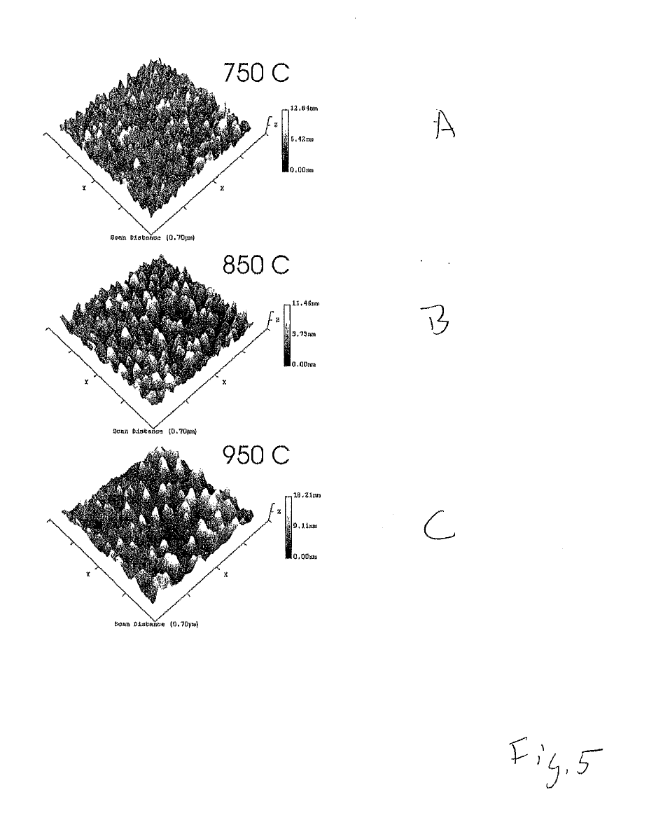

FIGS. 5A, 5B and 5C are AFM images of representative nanocolumnar template layers deposited at different temperatures, 750° C., 850° C., and 950° C., respectively. It can be seen that at different growth temperatures, the average column size and thus surface roughness change. It thus can be seen that the surface roughness of the template layer is strongly dependent on, and hence may be controlled by, the growth temperature. In this manner, the surface morphology, in this case the surface roughness, may be optimized to obtain better crystal quality of subsequently grown heterostructures and devices.

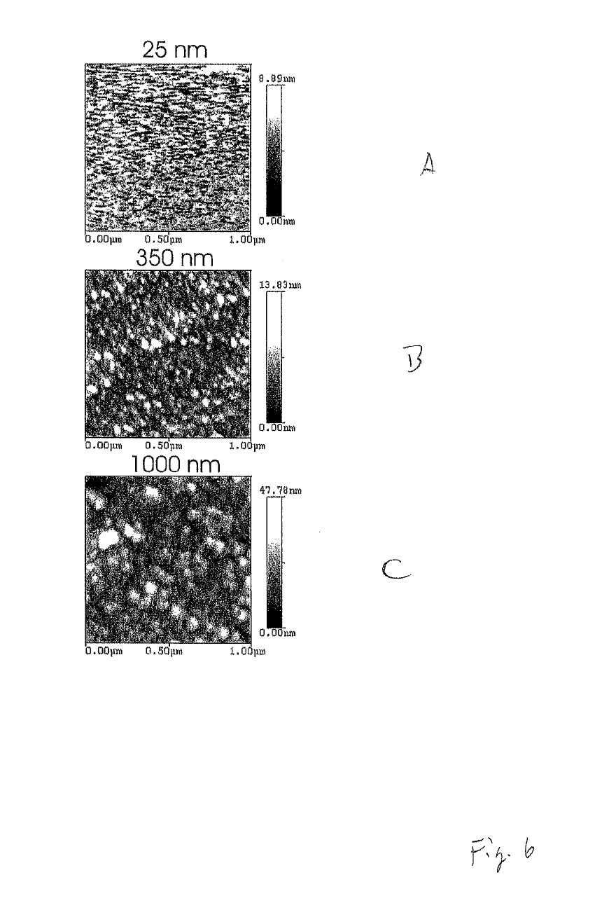

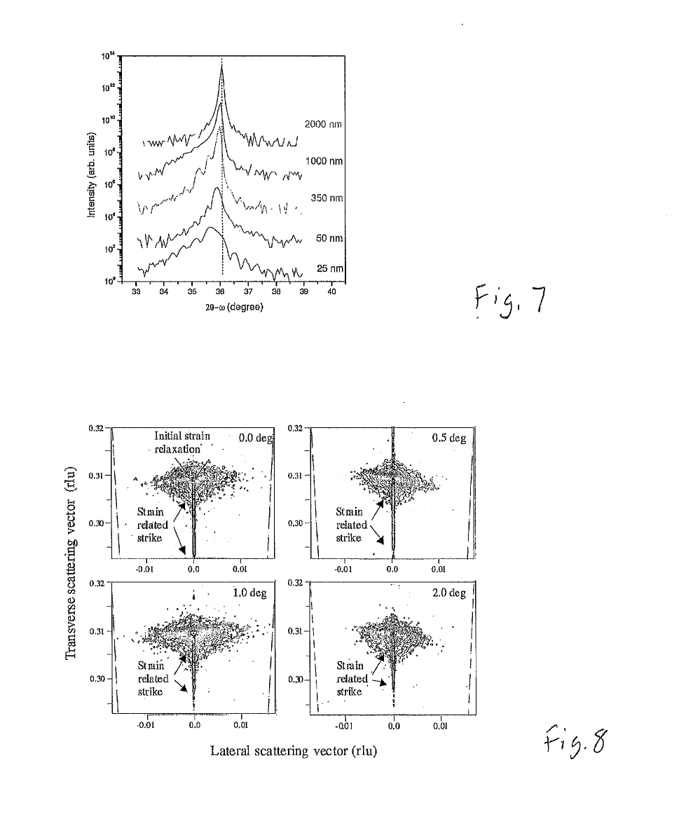

FIGS. 6A, 6B and 6C are AFM images of representative nanocolumnar template layers deposited to different thicknesses, 25 nm, 350 nm, and 1000 nm, respectively. At different thicknesses, the average column size and thus surface roughness change. It thus can be seen that the surface roughness of the template layer is strongly dependent on, and hence may be controlled by, the thickness of the deposited template material. In this manner, the surface morphology, in this case the surface roughness, may be optimized to obtain better crystal quality of subsequently grown heterostructures and devices.

FIG. 7 is a collection of XRD 2θ/ω scans around the symmetric 002 reflection of representative nanocolumnar template layers of different thicknesses, 25 nm, 50 nm, 350 nm, 1000 nm, and 2000 nm, respectively. FIG. 7 shows a shifting in the peak and a decrease in peak asymmetry with increasing layer thickness, which is indicative of strain variation upon changing the layer thickness. The strain e_{zz} in the nanocolumnar sublayer varies from 0.2×10⁻² to 0.4×10⁻², as calculated from various sample templated substrates grown. FIG. 7 demonstrates the presence of a highly-strained sublayer in template layers thinner than 500 Å, while a sublayer with initial relaxation appears in the template layer with a thickness of more than 700 Å, and a completely relaxed sublayer is present in template layers thicker than 1000 Å. It thus can be seen that the strain in the template layer is dependent on, and hence may be controlled by, the thickness of the deposited template material. In this manner, the strain may be optimized to obtain better crystal quality of subsequently grown heterostructures and devices.

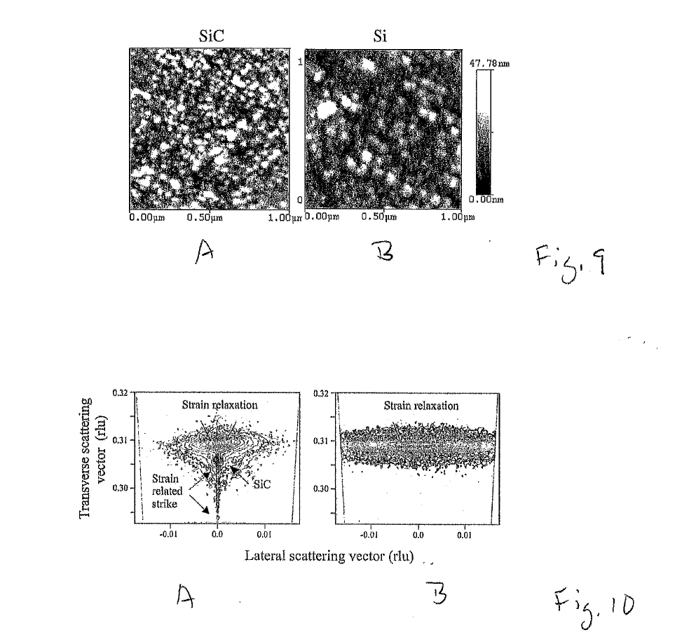

FIG. 8 is a set of XRD RSMs of representative template layers grown on sapphire substrates with different surface off-cuts (or miscuts), specifically 0.0°, 0.5°, 1.0° and 2.0°, respectively. It can be seen that the strain decreases with increasing degree of substrate off-cut. Thus, the strain in the template layer is dependent on, and hence may be controlled by, the off-cut of the base layer on which the template layer is deposited. In this manner, the strain may be optimized to obtain better crystal quality of subsequently grown heterostructures and devices.

FIG. 9A and 9B are AFM images of representative template layers grown on a SiC base layer and a Si base layer, respectively. The two template layers were otherwise grown under similar growth conditions, and have similar structures (continuous and nanocolumnar sublayers) and similar morphology. However, the column sizes in the respective template layers are different. It thus can be seen that the surface morphology of the template layer, particularly column size and hence surface roughness, is dependent on the composition of the base layer on which the template layer is deposited.

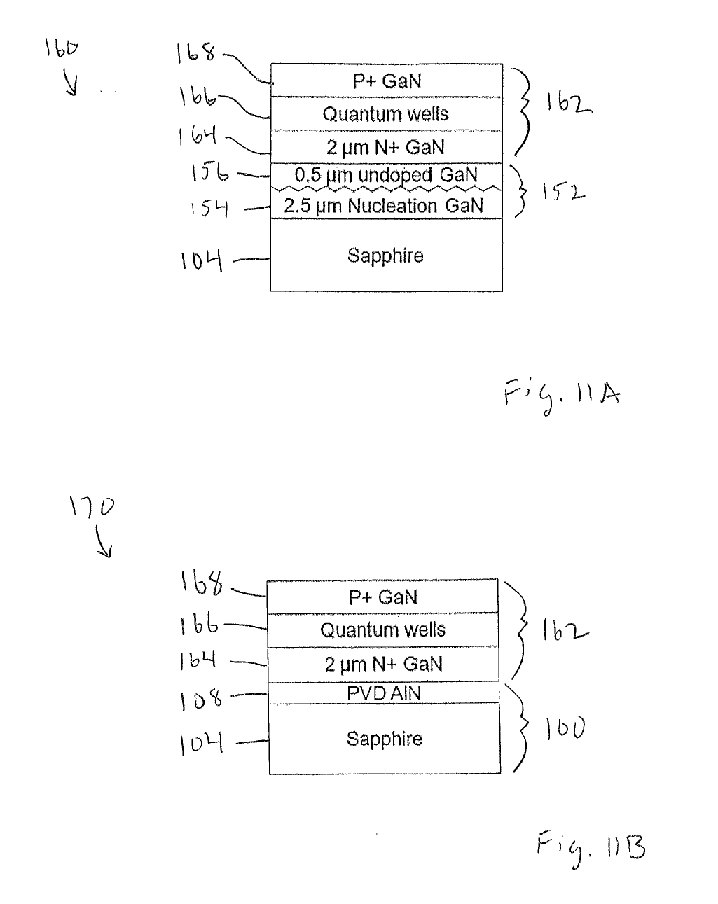

FIGS. 10A and 10B are RSMs of the same SiC and Si template layers illustrated in FIGS. 9A and 9B, respectively. FIGS. 10A and 10B demonstrate that the SiC and Si template layers have completely different strain statuses. The left RSM (FIG. 10A), corresponding to the AlN template layer on SiC base layer, shows the two main peaks of the SiC and AlN. FIG. 10A indicates the presence of a highly strained template sublayer due to the lateral lattice parameters of the AlN being similar to those of the SiC, as manifested by the perfect vertical alignment of the two maps relating to the two materials. The right RSM (FIG. 10B), corresponding to the AlN template layer on Si base layer, shows a single peak from the AlN, considerably broadened in the direction parallel to the surface plane as shown by the arrows. FIG. 10B indicates significant strain relaxation in the template layer, as the Si peak is not aligned with the AlN peak and indeed is out of the map range shown in FIG. 10B. The single-layer deposited template is characterized so that the line-width of the rocking curves are narrow in order to obtain better crystal quality of the subsequently grown heterostructures.

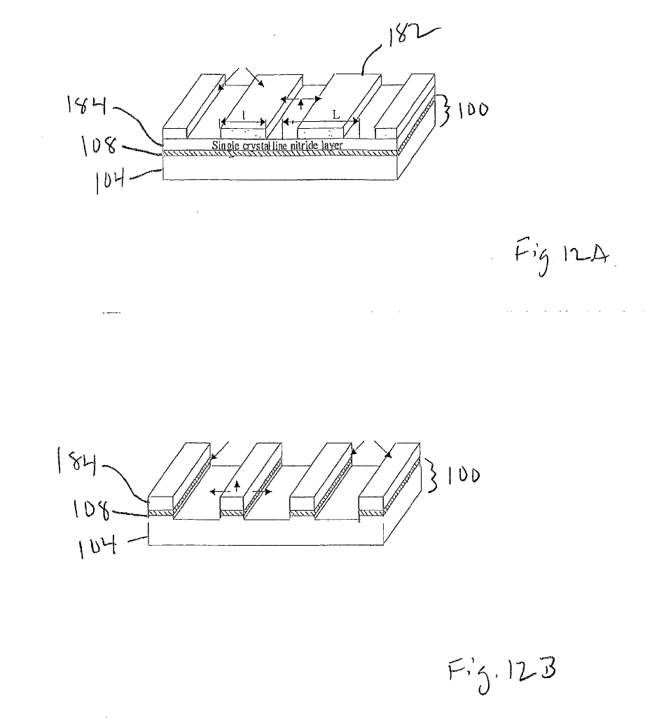

FIG. 11A is a schematic cross-sectional view of an example of a conventional LED device 160. The LED device 160 includes a sapphire substrate 104, an LT buffer structure 152 deposited on the sapphire substrate 104, and an LED device structure 162 deposited on the LT buffer structure 152. The LT buffer structure 152 and the LED device structure 162 are typically grown by metalorganic CVD (MOCVD). The LT buffer structure 152 is grown by a multi-step nucleation process in which a 2.5 μm GaN nucleation layer 154 is deposited on the sapphire substrate 104, followed by deposition of a 0.5 μm layer 156 of undoped GaN. The LED device structure 162 includes a layer 164 of N+ GaN (typically 2 μm), a quantum well layer 166 (single- or multi-quantum well), and a layer 168 of P+ GaN.

By comparison, FIG. 11B is a schematic cross-sectional view of an example of a LED device 170 fabricated according to the present teachings. The LED device 170 includes a templated substrate 100, and an LED device structure 162 deposited on the templated substrate 100. The templated substrate 100 includes a base layer 104 and a template layer 108 as described herein. By way of example and not by limitation, the template layer 108 may be or include A1N deposited by PVD as described above. For comparative purposes and not by way of limitation, the base layer 104 in this example is a sapphire substrate and the LED device structure 162 includes a N+ GaN layer 164, a quantum well layer 166, and a P+ GaN layer 168, as in the case of the known LED device 160 illustrated in FIG. 11A. The LED device structure 162 may be grown by MOCVD or any other suitable technique. It can be seen that the LED device 170 illustrated in FIG. 11B has a less complex and less expensive design as compared to the known LED device 160 illustrated in FIG. 11A. The single-step template layer 108 may be utilized as a substitute for the conventional LT buffer 152 or for any other conventional buffer or transition layers.

It will be understood that FIG. 11B is but one example of the various types of LED devices that could be fabricated from the templated substrate disclosed herein. More generally, it will be understood that an LED device is but one example of the various types of microelectronic devices and heterostructures that may be fabricated from the templated substrate 100 disclosed herein. As used herein, the term “microelectronic devices” generally encompasses devices and components such as, for example, optoelectronic devices such as light-emitting diodes (LEDs), laser diodes (LDs), solar cells, photodetectors and UV detectors, as well as biological or chemical sensors, other types of sensors or detectors, electronic or optical filters, field-effet transistors (FETs), other types of transistors, other types of diodes and rectification circuitry, microelectrode arrays, bond pads, metallization elements, and interconnects. Accordingly, implementations of the present disclosure include articles comprising the templated substrates with additional Group III nitride layers and/or Group III nitride-based microelectronic devices fabricated thereon.

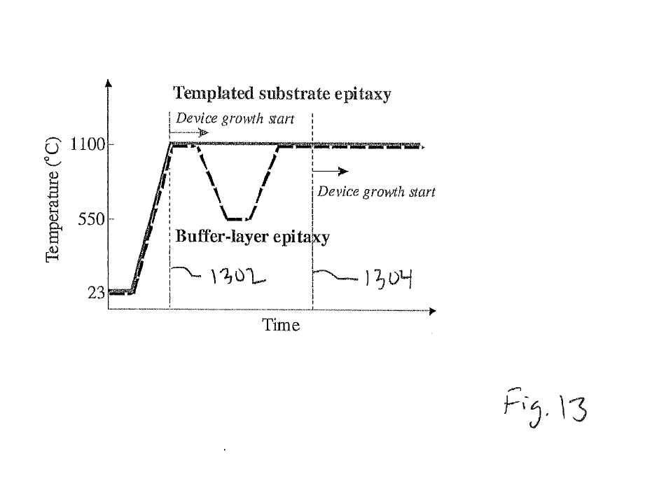

The single-step template layer 108 may also be utilized as a substitute for the conventional LT buffer in conjunction with fabrication techniques that employ complex patterned structures such as mask configurations. FIG. 12A is a perspective view of a templated substrate 100 as taught herein, including a base layer 104 and a template layer 108, on which a mask 182 (typically a dielectric material) has been deposited and patterned. The mask material may be deposited directly on the nanocolumnar surface of the template layer 108 or on an intermediate epitaxial Group III nitride layer 184. FIG. 12B is a perspective view of the templated substrate 100 illustrated in FIG. 12B, after performing etching and mask removal steps by any suitable techniques. As indicated by arrows, epitaxial Group III nitride material 184 may be grown vertically and laterally according to various known growth/overgrowth techniques such as those noted in the background section above.

FIG. 13 is a schematic time schedule comparing the shorter time required to fabricate a standard MOCVD LED device (such as illustrated in FIG. 11B) utilizing a templated substrate 100 as taught herein (solid line) with the longer time required to fabricate the same LED device (such as illustrated in FIG. 11A) utilizing a conventional LT buffer nucleation process (dashed line). The start of LED device growth after growing the template layer 108 as taught herein is indicated at 1302. The start of LED device growth after growing the conventional LT buffer layers is indicated at 1304, which is much further in time. The process lines are plotted as growth temperature as a function of time. It can be seen that the process taught herein does not require any low-temperature steps. The dip in the process line for the conventional LT buffer nucleation process corresponds to the required growth of the LT nucleation layer, which contributes to the longer time required for completing growth of the LT buffer structure before being able to initiate growth of the LED device structure thereon.

In the examples presented, impurities or dopants may be introduced into or deposited with the Group III nitride layers as needed or desired for a particular application. N-type, p-type, semi-insulating, insulating, non-polar or semi-polar Group III nitride layers may be grown as needed or desired.

Examples of the present invention utilize several specific growth sequences. It should be understood that these specific growth processes are meant for illustrative purposes and are not limiting. It should also be noted that growth conditions cited in the examples are specific to the growth reactor employed in the examples. When employing a different reactor design or reactor geometry, it may be desirable to utilize a different condition to achieve similar results. However, the general trends are still similar.

It will be understood that various aspects or details of the invention may be changed without departing from the scope of the invention. Furthermore, the foregoing description is for the purpose of illustration only, and not for the purpose of limitation the invention being defined by the claims.

What is claimed is:

1. A templated substrate, comprising:
a base layer; and
a template layer disposed on the base layer and having a composition including a single-crystal Group III nitride, the template layer comprising a continuous sublayer on the base layer and a nanocolumnar sublayer on the first sublayer, wherein the nanocolumnar sublayer comprises a plurality of nano-scale columns.

2. The templated substrate of claim 1, wherein the base layer comprises a material selected from the group consisting of sapphire, SiC, 6H-SiC, 4H-SiC, Si, MgAl₂O₄, and LiGaO₂.

3. The templated substrate of claim 1, wherein the base layer includes an off-cut orientation ranging from 0-2 degrees.

4. The templated substrate of claim 1, wherein the composition of the template layer is selected from the group consisting of GaN and AlN.

5. The templated substrate of claim 4, wherein the base layer is sapphire.

6. The templated substrate of claim 1, wherein the template layer includes a maximum lateral dimension of 2 inches or greater.

7. The templated substrate of claim 1, wherein the template layer includes a wurtzite crystalline structure.

8. The templated substrate of claim 1, wherein the template layer has a thickness ranging from 10-1000 nm.

9. The templated substrate of claim 1, wherein the nanocolumnar sublayer has a thickness ranging from 1-20 nm.

10. The templated substrate of claim 1, wherein the continuous sublayer has a first thickness and the nanocolumnar sublayer has a second thickness less than the first thickness.

11. The templated substrate of claim 1, wherein the template layer has a surface roughness ranging from 0.2-10 nm.

12. The templated substrate of claim 1, wherein the template layer has a strain value ranging from 0.2×10⁻² to 0.8×10⁻².

13. The templated substrate of claim 1, wherein the template layer has a crystal quality characterized by a rocking curve FWHM ranging from 100-500 arcsecs for the nanocolumnar sublayer and ranging from 500-2500 arcsecs for the continuous sublayer.

14. The templated substrate of claim 1, wherein the columns have a substantially conical shape and terminate at respective tips.

15. The templated substrate of claim 1, wherein the columns include respective column bases having respective lateral dimensions, and the average lateral dimension of the column bases ranges from 10-150 nm.

16. The templated substrate of claim 1, wherein the columns have respective heights, and the average height of the columns ranges from 1-20 nm.

17. A heterostructure comprising:
a base layer;
a template layer disposed on the base layer and having a composition including a single-crystal Group III nitride, the template layer comprising a continuous sublayer on the base layer and a nanocolumnar sublayer on the first sublayer, wherein the nanocolumnar sublayer comprises a plurality of nano-scale columns; and
a Group III nitride-inclusive heterostructures disposed on the nanocolumnar sublayer.

18. A method for fabricating a templated substrate, the method comprising:
growing a single-crystal Group III nitride-inclusive template layer on a base layer by vacuum deposition, wherein growing comprises:
forming a continuous sublayer on the base layer; and
forming a nanocolumnar sublayer on the continuous sublayer, wherein the nanocolumnar sublayer comprises a plurality of nano-scale columns.

19. The method of claim 18, wherein the template layer is grown by sputtering.

20. The method of claim 18, wherein the template layer is grown at a growth rate of less than 1 μm/hr, achieved in a mixed-gas environment at temperature greater than 500° C.

21. The method of claim 18, wherein forming the continuous sublayer and forming the nanocolumnar sublayer occur at the same growth temperature.

22. The method of claim 18, wherein the template layer is grown to a thickness ranging from 10-1000 nm.

23. The method of claim 18, wherein the nanocolumnar sublayer is formed to a thickness ranging from 1-20 nm

24. The method of claim 18, wherein the columns have a substantially conical shape and terminate at respective tips.

25. The method of claim 18, wherein the columns include respective column bases having respective lateral dimensions, and the average lateral dimension of the column bases ranges from 10-150 nm.

26. The method of claim 18, wherein the columns have respective heights, and the average height of the columns ranges from 1-20 nm

27. The method of claim 18, further comprising controlling a size of the columns by controlling a parameter selected from the group consisting of a growth temperature at which the template layer is grown, a size of the columns by controlling a thickness to which the template layer is grown, and a composition of the base layer.

28. The method of claim 18, further comprising controlling a strain value of the template layer by controlling a parameter selected from the group consisting of a thickness to which the template layer is grown, an off-cut orientation of the base layer, and a composition of the base layer.

29. The method of claim 18, further comprising growing a Group III nitride-inclusive epitaxial layer on the nanocolumnar sublayer.

30. A templated substrate fabricated according to the method of claim 18.
